(19) United States
(12) Patent Application Publication
(10) Pub. No.: US 2012/0114838 A1
(43) Pub. Date: May 10, 2012

(54) FILM FORMATION APPARATUS

(75) Inventors: Yoshiyuki Nakagawa, Chiba-shi (JP); Shingo Nakano, Chiba-shi (JP); Naoto Fukuda, Chiba-shi (JP)

(73) Assignee: CANNON KABUSHIKI KAISHA, Tokyo (JP)

(21) Appl. No.: 13/281,077

(22) Filed: Oct. 25, 2011

(30) Foreign Application Priority Data
Nov. 4, 2010 (JP) 2010-247819
Sep. 28, 2011 (JP) 2011-211801

(51) Int. Cl. C23C 16/52; C23C 16/448

(52) U.S. Cl. 427/9; 118/712

(57) ABSTRACT

A film formation apparatus includes a film formation source, a quartz oscillator for measurement, and a quartz oscillator for calibration. When a thin film of a film forming material is formed on a film formation object, the film forming material is heated in the film formation source to release vapors thereof. The quartz oscillator for measurement measures the amount of the film forming material formed on the film formation object, while the quartz oscillator for calibration calibrates the quartz oscillator for measurement. In the film formation apparatus, there are further provided a moving part for moving the film formation source between a predetermined film formation waiting position and a predetermined film forming position with respect to the film formation object and a temperature control part for controlling a temperature of the quartz oscillator for measurement and a temperature of the quartz oscillator for calibration to be substantially the same.

### BACKGROUND OF THE INVENTION

1. Field of the Invention

The present invention relates to a film formation apparatus.

2. Description of the Related Art

Conventionally, when a thin film is formed on a film formation object such as a substrate by evaporation, sputtering, or the like, in order to control the thickness of the thin film to be formed, a quartz oscillator is placed in a film formation chamber. When a quartz oscillator is placed in the film formation chamber, in forming the thin film, a film forming material forming the thin film is deposited both on the quartz oscillator and on the film formation object. Here, as the film forming material is deposited on the quartz oscillator, the resonance frequency of the quartz oscillator changes according to the amount of the film forming material deposited thereon. Using this phenomenon, the thickness of the film of the film forming material deposited on the film formation object may be known. Specifically, the thickness of the film deposited on the quartz oscillator is calculated from the amount of change in resonance frequency. With the film thickness ratio between the film deposited on the quartz oscillator and the film deposited on the film formation object which is determined in advance, the thickness of the film of the film forming material deposited on the film formation object may be known.

However, as the film forming material is deposited on the quartz oscillator, the relationship between the amount of change in resonance frequency and the thickness value of the film deposited on the film formation object is deviated from the calculated values. Therefore, it is difficult to control the thickness of the film on the film formation object with accuracy for a long period of time.

Japanese Patent Application Laid-Open No. 2008-122200 discloses a method of making smaller a film thickness value error which presents a problem in controlling the thickness of a film on a film formation object. More specifically, in Japanese Patent Application Laid-Open No. 2008-122200, a method is adopted in which, in addition to a conventional quartz oscillator for measurement, a quartz oscillator for calibration is provided in a film formation chamber.

By the way, in an ordinary film formation step, first, the film formation object is brought into the film formation chamber, and a film is formed on the film formation object. Here, when the film is formed on the film formation object, the film forming material is deposited on the quartz oscillator for measurement to control the thickness of the film on the film formation object. After the film formation is completed, the film formation object is taken out of the film formation chamber, and the film formation step is completed. However, when the film formation step is repeated multiple times, the film forming material is deposited on the quartz oscillator for measurement each time the film formation step is performed, and thus, the accuracy of the film thickness control is lowered as the film formation step is repeated. Therefore, the quartz oscillator for calibration is used to carry out a calibration step.

In the film formation method disclosed in Japanese Patent Application Laid-Open No. 2008-122200, the calibration step is performed between film formation steps, that is, after a film formation step is completed and before the subsequent film formation step is started. In this calibration step, first, the film forming material is deposited both on the quartz oscillator for calibration and on the quartz oscillator for measurement. Then, the thickness of the thin film formed on the film formation object which is determined using the quartz oscillator for calibration (film thickness value P₀) and the thickness of the thin film formed on the film formation object which is determined using the quartz oscillator for measurement (film thickness value M₀) are measured, and a calibration coefficient P₀/M₀ is determined. Then, in the film formation step which is performed after the calibration step, by multiplying a film thickness value M₁ of the film formation object which is calculated using the quartz oscillator for measurement by the calibration coefficient P₀/M₀ which is determined in advance, the thickness of the film on the film formation object is controlled with accuracy.

On the other hand, Japanese Patent Application Laid-Open No. 2004-091919 discloses an apparatus and a method for forming a film having a uniform thickness on a surface of a film formation object. In the thin film formation apparatus disclosed in Japanese Patent Application Laid-Open No. 2004-091919, a movable film formation source moves with constant speed below a fixed film formation object. By forming a thin film using the thin film formation apparatus, a film having a uniform thickness may be formed on the film formation object even if the film formation object has a large area.

Further, in the thin film formation apparatus disclosed in Japanese Patent Application Laid-Open No. 2004-091919, in order to monitor the amount of the film forming material released from the film formation source, a film thickness sensor is provided which is fixed above a waiting position of the film formation source. The film thickness sensor may detect the film forming speed of the film forming material, and thus, at the time when the film forming speed reaches a desired level, the film formation source moves to a film forming position to form a film on the film formation object.

However, in the thin film formation apparatus disclosed in Japanese Patent Application Laid-Open No. 2004-091919, when a quartz oscillator is used as the film thickness sensor, as the film forming material is deposited on the quartz oscillator, the relationship between the amount of change in resonance frequency and the thickness value of the deposited film is deviated from the calculated values. As a result, film formation with accuracy cannot be carried out for a long period of time.

Further, when the film formation method disclosed in Japanese Patent Application Laid-Open No. 2008-122200 is adopted, the quartz oscillator for measurement continues to bask in radiant heat generated from a film formation source while the film formation step is carried out, and thus, the temperature of the quartz oscillator for measurement itself rises. On the other hand, with regard to the quartz oscillator for calibration, a film is prevented from being deposited on the quartz oscillator for calibration by a shutter while the film formation step is carried out, and thus, the radiant heat generated from the film formation source is also blocked at the same time and the temperature of the quartz oscillator for calibration almost does not rise. However, when the shutter of the quartz oscillator for calibration is opened after the film formation step and while the calibration step is carried out, the quartz oscillator for calibration basks in the radiant heat generated from the film formation source, and the temperature of the quartz oscillator for calibration itself rises. Here, the difference between the temperature of the quartz oscillator for measurement which basks in the radiant heat all the time and the temperature of the quartz oscillator for calibration which basks in the radiant heat intermittently becomes very large.

Here, the resonance frequency of a quartz oscillator changes by a film deposited on the quartz oscillator, but the resonance frequency also changes by temperature change of the quartz oscillator itself.

Accordingly, the inventors of the present invention measured and evaluated the extent of change in resonance frequency of a quartz oscillator due to the radiant heat generated from a film formation source. FIG. 5 is a schematic view of an apparatus which was used for measuring the amount of change in resonance frequency of the quartz oscillator due to the radiant heat generated from a film formation source. In the apparatus illustrated in FIG. 5, a quartz oscillator 102 is placed immediately above a film formation source 101 at a predetermined distance therefrom, and a shutter 103 is placed between the film formation source 101 and the quartz oscillator 102. In this experiment, as the film formation source 101, a cylindrical crucible having a radius of 50 mm and a height of 150 mm was used, and, as the quartz oscillator 102, a 6 MHz quartz oscillator having gold electrodes and manufactured by INFICON was used to perform the experiment.

In the experiment, first, the film formation source having no film forming material therein was heated to 300° C. After that, the shutter 103 was opened. The amount of change in resonance frequency of the quartz oscillator 102 after the shutter 103 was opened was measured and evaluated. FIG. 6 is a graph illustrating the result of the above-mentioned measurement. In FIG. 6, the horizontal axis is the heating time of the film formation source while the vertical axis is the resonance frequency and the temperature of the quartz oscillator. As illustrated in FIG. 6, when the shutter 103 was opened and the quartz oscillator 102 began to be heated by the radiant heat, the temperature of the quartz oscillator 102 gradually rose and was stabilized about two minutes later. On the other hand, the resonance frequency of the quartz oscillator 102 was lowered as the temperature of the quartz oscillator 102 rose, and was stabilized according to the stabilization of the temperature.

When the above-mentioned result of the experiment is taken into consideration, in the film formation method disclosed in Japanese Patent Application Laid-Open No. 2008-122200, the quartz oscillator for measurement continues to bask in the radiant heat generated from the film formation source both while the film formation step is carried out and while the calibration step is carried out, and thus, the temperature is stable and the resonance frequency does not change. However, the quartz oscillator for calibration basks in the radiant heat generated from the film formation source only during the calibration step which is carried out only for a few minutes, and thus, while the calibration step is carried out, the temperature of the quartz oscillator for calibration changes and the resonance frequency thereof changes accordingly. As a result, there is a problem that change in resonance frequency of the quartz oscillator for calibration due to the radiant heat lowers the accuracy of the film thickness calibration.

### SUMMARY OF THE INVENTION

The present invention has been accomplished to solve the problem described above, and an object of the present invention is to provide a film formation apparatus capable of forming a uniform film on a film formation object with accuracy.

According to the present invention, there is provided film formation apparatus, which includes: an evaporation source for heating a film forming material and for releasing vapors of the film forming material; a moving part for moving the evaporation source between a predetermined film formation waiting position and a predetermined film forming position with respect to a film formation object; a quartz oscillator for measurement for measuring an amount of the film forming material formed on the film formation object; and a quartz oscillator for calibration for calibrating the amount of the film forming material measured by the quartz oscillator for measurement, wherein the quartz oscillator for measurement and the quartz oscillator for calibration are fixed above the predetermined film formation waiting position of the evaporation source.

According to the present invention, it is possible to provide the film formation apparatus capable of forming a uniform film on the film formation object with accuracy.

Further features of the present invention will become apparent from the following description of exemplary embodiments with reference to the attached drawings.

### BRIEF DESCRIPTION OF THE DRAWINGS

FIGS. 1A and 1B are schematic views illustrating a film formation apparatus according to an embodiment of the present invention, which is obtained when a film formation source is at a film formation waiting position, and FIGS. 1C and 1D are schematic views illustrating the film formation apparatus according to the embodiment of the present invention, which are obtained when the film formation source is at a film forming position.

FIG. 2 is a circuit block diagram illustrating a control system of the film formation apparatus illustrated in FIGS. 1A to 1D.

FIG. 3 is a flow chart illustrating a thickness control flow of a film of a film forming material formed on a film formation object.

FIG. 4 is a graph which compares the thickness of a thin film formed on the film formation object when a calibration step is performed to that when the calibration step is not performed.

FIG. 5 is a schematic view of an apparatus which was used for measuring the amount of change in resonance frequency of a quartz oscillator due to radiant heat generated from a film formation source.

FIG. 6 is a graph illustrating the result of the measurement of the amount of change in resonance frequency of the quartz oscillator which was carried out using the apparatus illustrated in FIG. 5.

### DESCRIPTION OF THE EMBODIMENT

Preferred embodiments of the present invention will now be described in detail in accordance with the accompanying drawings.

A film formation apparatus according to the present invention includes a film formation source, a quartz oscillator for measurement, and a quartz oscillator for calibration.

In the film formation apparatus according to the present invention, when a thin film of a film forming material is formed on a film formation object, the film forming material is heated in the film formation source to release vapors of the film forming material.

In the film formation apparatus according to the present invention, the quartz oscillator for measurement is provided for the purpose of measuring the amount of the film of the film forming material formed on the film formation object (thickness of the thin film formed on the film formation object).

In the film formation apparatus according to the present invention, the quartz oscillator for calibration is provided for the purpose of calibrating the quartz oscillator for measurement. Note that, the timing at which a calibration step in which the quartz oscillator for calibration calibrates the quartz oscillator for measurement is carried out is arbitrary.

The film formation apparatus according to the present invention has a moving part for relatively moving the film formation source between a predetermined film formation waiting position and a predetermined film forming position with respect to the film formation object.

It is preferred that the film formation apparatus further have a temperature control part which causes the temperature of the quartz oscillator for measurement and the temperature of the quartz oscillator for calibration to be substantially the same. Note that, there may be an error to some extent between the temperature of the quartz oscillator for measurement and the temperature of the quartz oscillator for calibration. More specifically, “to be substantially the same” means being in a range of a set temperature with an error of ±0.5° C.

The film formation apparatus according to the present invention is described in the following with reference to the attached drawings, but the present invention is not limited thereto. Further, appropriate modifications can be made thereto without departing from the gist of the present invention.

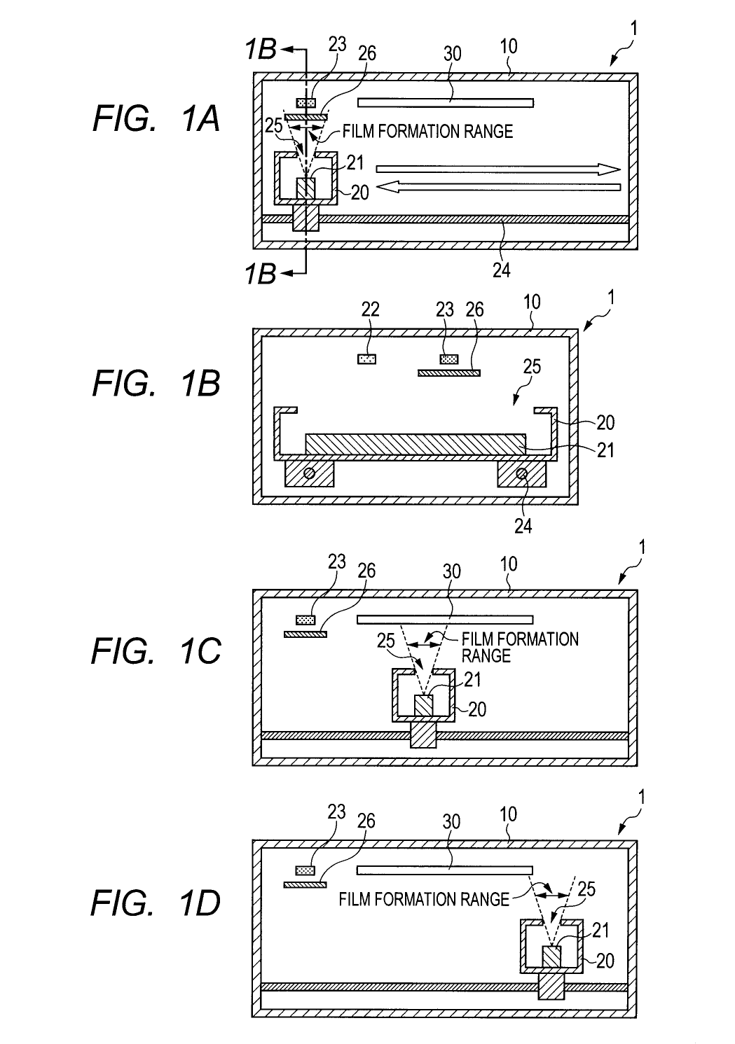

FIGS. 1A and 1B are schematic views illustrating a film formation apparatus according to an embodiment of the present invention, which are obtained when the film formation source is at the film formation waiting position, and FIGS. 1C and 1D are schematic views illustrating the film formation apparatus according to the embodiment of the present invention, which are obtained when the film formation source is at the film forming position. Note that, FIGS. 1A, 1C, and 1D are schematic sectional views of the film formation apparatus when viewed from the front side (in the width direction), and FIG. 1B is a schematic sectional view of the film formation apparatus taken along the line 1B-1B of FIG. 1A when viewed from the left side (in the depth direction).

In a film formation apparatus 1 illustrated in FIGS. 1A to 1D, a film formation source unit 20 as a moving part for moving a film formation source 21 and two kinds of quartz oscillators (quartz oscillator 22 for measurement and quartz oscillator 23 for calibration) are provided at predetermined positions in a film formation chamber 10. Note that, the positions at which the two quartz oscillators are provided are described below.

In the following, members forming the film formation apparatus 1 illustrated in FIGS. 1A to 1D are described. Note that, the film formation apparatus 1 illustrated in FIGS. 1A to 1D is used in, for example, manufacturing an organic electroluminescent (EL) element.

In the film formation apparatus 1 illustrated in FIGS. 1A to 1D, the film formation chamber 10 is connected to a vacuum exhaust system (not shown). The vacuum exhaust system may exhaust the film formation chamber 10 so that the pressure therein is in a range of 1.0×10⁻⁴ Pa to 1.0×10⁻⁶ Pa.

In the film formation apparatus 1 illustrated in FIGS. 1A to 1D, the film formation source unit 20 may reciprocate along a rail 24 provided in the film formation chamber 10 in the direction of arrows illustrated in FIG. 1A, more specifically, between the film formation waiting position and the film forming position. Here, the film formation waiting position is a position of the film formation source unit 20 when a film of the film forming material is not formed on a film formation object 30. More specifically, as illustrated in FIG. 1A, the film formation waiting position is a position of the film formation source unit 20 when the film formation object 30 is not at a position vapors of the film forming material released from the film formation source 21 may reach (film formation range). On the other hand, the film forming position is a position of the film formation source unit 20 when a film of the film forming material is formed on the film formation object 30. More specifically, as illustrated in FIGS. 1C and 1D, the film forming position is a position of the film formation source unit 20 when the film formation object 30 is at a position at which vapors of the film forming material released from the film formation source 21 may reach (film formation range).

Note that, in the present invention, the shape of the film formation source unit 20 is not specifically limited, but, from the viewpoint of selectively releasing vapors of the film forming material from a predetermined position, it is preferred that the film formation source unit 20 be a box having an opening 25 provided in an upper portion thereof for releasing vapors of the film forming material. By causing the film formation source unit 20 to be a box, the direction of travel and the distribution of vapors of the film forming material released from the film formation source unit 20 may be controlled by the shape of the opening 25. Further, in the present invention, the size of the film formation source unit 20 is not specifically limited. Note that, the size of the film formation source unit 20 is appropriately set taking into consideration the balance thereof with other members including the film formation chamber 10.

When the film formation source unit 20 reciprocates along the rail 24 between the film formation waiting position and the film forming position as illustrated in FIG. 1A, a movement control part (not shown) may be provided in the film formation source unit 20. In particular, if the movement control part may move the film formation source unit 20 with constant speed, a film of the film forming material may be uniformly formed on the film formation object 30, which is preferred.

The shape of the film formation source 21 provided in the film formation source unit 20 may be appropriately set taking into consideration the size of the film formation object 30 and the distribution of vapors of the film forming material. For example, as illustrated in FIGS. 1A and 1B, the film formation source 21 may be in the shape of a rectangular parallelepiped having a dimension in a width direction of the film formation chamber 10 which is smaller than that in a depth direction of the film formation chamber 10, but the present invention is not limited thereto. Further, multiple film formation sources 21 may be provided in the film formation source unit 20. The film forming material (not shown) is housed in the film formation source 21 which is provided in the film formation source unit 20. By heating the film forming material with a heating part (not shown) provided in the film formation source 21, vapors of the film forming material may be released from the film formation source 21.

In the film formation apparatus 1 illustrated in FIGS. 1A to 1D, when the film formation source unit 20 is at the film formation waiting position, the two kinds of quartz oscillators (quartz oscillator 22 for measurement and quartz oscillator 23 for calibration) are provided immediately above the film formation source unit 20.

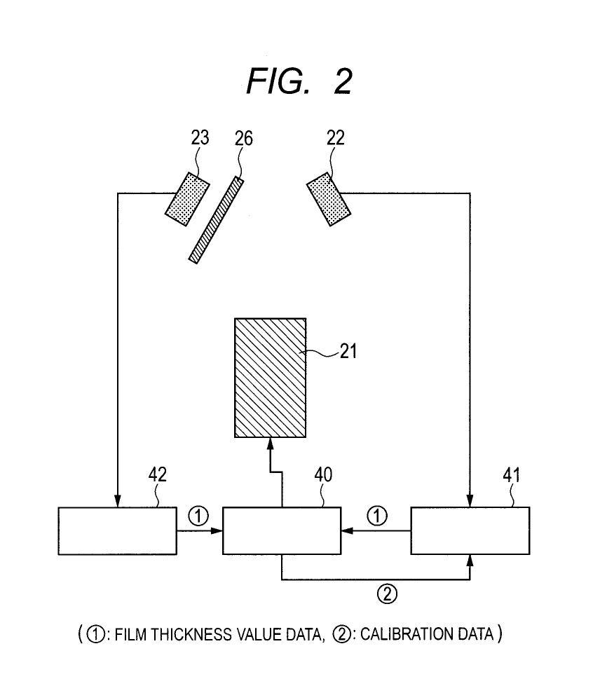

It is preferred that the quartz oscillator 22 for measurement be placed at a position at which the quartz oscillator 22 for measurement may monitor the amount of the film forming material released from the film formation source 21 when the film formation source unit 20 is at the film formation waiting position. The deposition of the film forming material on the quartz oscillator 22 for measurement changes the resonance frequency of the quartz oscillator 22 for measurement. FIG. 2 is a circuit block diagram illustrating a control system of the film formation apparatus illustrated in FIGS. 1A to 1D. As illustrated in FIG. 2, the amount of change in resonance frequency of the quartz oscillator 22 for measurement is sensed by a film thickness measurement device 41. Then, an electrical signal which is output from the film thickness measurement device 41 (electrical signal concerning information of the amount of change in resonance frequency of the quartz oscillator 22 for measurement) is sent to a thermoregulator (not shown) provided in a control system 40 to control the heating part of the film formation source 21, for example, to adjust the heating temperature of the film forming material. In this way, the amount of the film forming material released from the film formation source 21 is controlled to be constant.

As illustrated in FIGS. 1A to 1D, it is also preferred that the quartz oscillator 23 for calibration be placed at a position at which the quartz oscillator 23 for calibration may monitor the amount of the film forming material released from the film formation source 21 when the film formation source unit 20 is at the film formation waiting position. In the calibration step, the deposition of the film forming material on the quartz oscillator 23 for calibration changes the resonance frequency of the quartz oscillator 23 for calibration. As illustrated in FIG. 2, the amount of change in resonance frequency of the quartz oscillator 23 for calibration due to the deposition of the film forming material is sensed by a film thickness measurement device 42. Then, an electrical signal which is output from the film thickness measurement device 42 (electrical signal concerning information of the amount of change in resonance frequency of the quartz oscillator 23 for calibration) is sent to the control system 40, and is then sent to the quartz oscillator 22 for measurement to calibrate the quartz oscillator 22 for measurement.

Note that, in the film formation apparatus illustrated in FIGS. 1A to 1D, a sensor shutter 26 is provided in proximity to the quartz oscillator 23 for calibration. By providing the sensor shutter 26, the film forming material may be caused to attach to the respective quartz oscillators at a predetermined timing and vapors of the film forming material may be blocked at a predetermined timing. The sensor shutter 26 blocks radiant heat which is generated from the film formation source 21 and received by the quartz oscillator 23 for calibration, and thus, a temperature rise of the quartz oscillator 23 for calibration in measuring the film thickness is suppressed.

The quartz oscillator 22 for measurement is fixed at the film formation waiting position of the film formation source unit 20, and thus, receives radiant heat generated from the evaporation source only when the film formation source unit 20 is at the film formation waiting position, and does not receive radiant heat generated from the evaporation source when the film formation source unit is at the film forming position. Therefore, the temperature of the quartz oscillator 22 for measurement rises when the film formation source unit 20 is at the film formation waiting position, but, when the film formation source unit 20 moves to the film forming position, heat of the quartz oscillator 22 for measurement is dissipated via a member for supporting the quartz oscillator 22 for measurement and the temperature of the quartz oscillator 22 for measurement falls to be substantially equal to the temperature of the quartz oscillator 23 for calibration. Therefore, compared to a structure in which the quartz oscillator 22 for measurement moves together with the film formation source, the temperature difference between the quartz oscillator 22 for measurement and the quartz oscillator 23 for calibration may be caused to be smaller.

Further, it is more preferred that the environments under which the respective quartz oscillators (quartz oscillator 22 for measurement and quartz oscillator 23 for calibration) receive heat be uniformized as much as possible. By, here, uniformizing the environments under which the respective quartz oscillators receive heat, the amounts of temperature rises of the quartz oscillators, respectively, due to radiant heat received by the quartz oscillators and generated from the film formation source 21 may be brought closer to each other. Then, change in resonance frequency of the quartz oscillator 22 for measurement due to heat and change in resonance frequency of the quartz oscillator 23 for calibration due to heat may be uniformized and the film thickness value measured using the quartz oscillator 22 for measurement may be calibrated, and thus, the film thickness may be controlled with high accuracy. In order to uniformize the environments under which the quartz oscillator 22 for measurement and the quartz oscillator 23 for calibration receive heat, it is preferred that the quartz oscillator 22 for measurement and the quartz oscillator 23 for calibration be fixed at positions at which the distances between the respective quartz oscillators and the center of the film formation source 21 are equal to each other and at which the angles formed by the respective quartz oscillators and the center of the film formation source 21 are equal to each other. For example, as illustrated in FIGS. 1A and 1B, the quartz oscillator 22 for measurement and the quartz oscillator 23 for calibration are fixed at positions, above the film formation waiting position, at which the distances between the respective quartz oscillators and the center of the film formation source 21 are equal to each other and at which the angles formed by the respective quartz oscillators and the center of the film formation source 21 are equal to each other.

Further, taking into consideration the dependence of the quartz oscillators on resonance frequency, it is more preferred that the temperature control part for positively uniformizing the temperatures of the quartz oscillators be provided. The temperature control part may be, for example, a heating part (not shown) or a cooling part (not shown) provided in proximity to the quartz oscillator 23 for calibration. Similarly, a heating part (not shown) or a cooling part (not shown) may also be provided in proximity to the quartz oscillator 22 for measurement.

In the film formation apparatus 1 illustrated in FIGS. 1A to 1D, the film formation object 30 such as a substrate is brought into the film formation chamber 10 and is taken out of the film formation chamber 10 by a transport mechanism (not shown). When the film formation object 30 is brought into the film formation chamber 10, a support member (not shown) is used to support the film formation object 30 at a predetermined position.

Next, a specific example of a film formation method using the film formation apparatus according to the present invention is described.

First, as a preliminary stage of the film formation, a preliminary step of measuring the thickness of a film deposited on the quartz oscillator 22 for measurement per unit time, the thickness of a film deposited on the quartz oscillator 23 for calibration per unit time, and the thickness of a film deposited on the film formation object 30 and determining a film thickness ratio based on the measured values is performed.

In this preliminary step, first, the film formation object 30 is brought into the film formation chamber 10 by the transport mechanism (not shown). Then, at the time when the amount of the film forming material released from the film formation source 21 reaches a desired level, movement of the film formation source unit 20 is started and a thin film of the film forming material is formed on the film formation object 30. After reciprocating the film formation source unit 20 a predetermined number of times under predetermined movement conditions, the transport mechanism (not shown) is used to take the film formation object 30 out of the film formation chamber 10.

With regard to the thin film formed on the film formation object 30 which has been taken out here, the thickness of the thin film is measured using an optical film thickness measurement device or a contact film thickness measurement device. The measured value (film thickness value) is assumed to be t. On the other hand, the thickness of the thin film deposited on the quartz oscillator 22 for measurement per unit time when the film of the film forming material is formed on the film formation object 30 may be calculated from the amount of change in resonance frequency of the quartz oscillator 22 for measurement. Here, the thickness of the thin film deposited on the quartz oscillator 22 for measurement per unit time (film thickness value) is assumed to be M. Then, the ratio α of t to M (film thickness ratio) is expressed as α=t/M.

Similarly to the case of the quartz oscillator 22 for measurement, the thickness of the thin film deposited on the quartz oscillator 23 for calibration per unit time calculated from the amount of change in resonance frequency of the quartz oscillator 23 for calibration (film thickness value) is assumed to be P. Then, the ratio β of t to P (film thickness ratio) is determined by β=t/p. Note that, β may be expressed as β(=t/P)=α×M/P.

Here, it is preferred that excess deposition of the film forming material on the quartz oscillator 23 for calibration be prevented by providing the sensor shutter 26 in proximity to the quartz oscillator 23. This may lengthen the time period during which the accuracy of measuring the film thickness provided by the quartz oscillator 23 for calibration remains high.

After the film thickness ratios α and β are determined as described above, the film formation step of forming a film of the film forming material on the film formation object 30 is performed.

In the film formation step, first, a substrate which is the film formation object 30 is brought into the film formation chamber 10. Then, the film formation source unit 20 is caused to reciprocate under predetermined conditions between the film formation waiting position and the film forming position and the film of the film forming material is formed on the film formation object 30. After the film formation is completed, the film formation object is taken out of the film formation chamber 10. By repeating the film formation step, a film of the film forming material may be formed on multiple film formation objects 30.

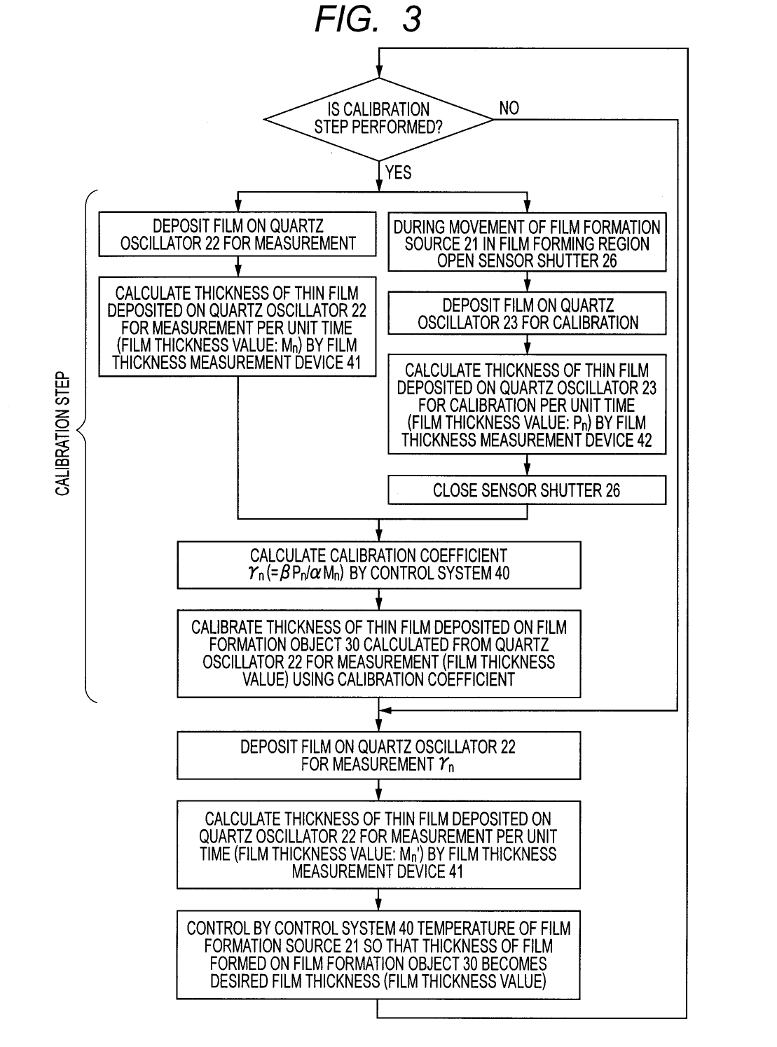

FIG. 3 is a flow chart illustrating a thickness control flow of the film of the film forming material formed on the film formation object 30. Note that, in the flow chart illustrated in FIG. 3, a flow chart illustrating the calibration step is also included. In the following, description is made also with reference to the circuit block diagram of FIG. 2.

First, when the calibration step is not performed, while the sensor shutter 26 in proximity to the quartz oscillator 23 for calibration is closed, the film forming material is deposited on the quartz oscillator 22 for measurement. Here, the film thickness measurement device 41 electrically connected to the quartz oscillator 22 for measurement measures the amount of change in resonance frequency of the quartz oscillator 22 for measurement. From the amount of change in resonance frequency measured by the film thickness measurement device 41, a thickness of the thin film (film thickness value M₀′) deposited on the quartz oscillator 22 for measurement per unit time is calculated in the film thickness measurement device 41. Then, the film thickness measurement device 41 sends the film thickness value M₀′ to the thermoregulator (not shown) provided in the control system 40 which is electrically connected thereto, and determines the thickness of the thin film deposited on the film formation object 30, that is, a film thickness value t₀ (=α×M₀′). Here, if t₀ is larger than a desired film thickness, an electrical signal is sent from the film thickness measurement device 41 to the thermoregulator (not shown) provided in the control system 40 so that the thermoregulator lowers the temperature of the film formation source 21. On the other hand, if t₀ is smaller than the desired film thickness, an electrical signal is sent from the film thickness measurement device to the thermoregulator so that the thermoregulator raises the temperature of the film formation source 21. When t₀ is equal to the desired film thickness, an electrical signal is sent from the film thickness measurement device 41 to the thermoregulator so that the thermoregulator maintains the temperature of the film formation source 21. Note that, in the film formation apparatus 1 illustrated in FIGS. 1A to 1D, movement of the film formation source unit 20 is configured to be started after confirming that the amount of the film forming material released from the film formation source 21 is stabilized at a desired level. Further, during the movement of the film formation source unit 20 in the film formation region, the temperature of the film formation source 21 is maintained at a fixed level. This may cause the amount of the film forming material released from the film formation source 21 to be constant during the movement of the film formation

However, during operation of the film formation source 21, the film forming material is deposited on the quartz oscillator 22 for measurement each time the film formation source unit 20 moves to the film formation waiting position, and thus, the accuracy of measuring the film thickness is gradually lowered. In such a case, the calibration step described below is performed.

With regard to the calibration step, the sensor shutter 26 in proximity to the quartz oscillator 23 for calibration is opened at a predetermined timing in the film formation step. More specifically, by opening the shutter at a predetermined timing while the film formation source 21 moves in the film formation region to wait, the temperature difference between the quartz oscillator 22 for measurement and the quartz oscillator 23 for calibration in the calibration step may be controlled to be smaller. For example, by opening the shutter 26 immediately before the quartz oscillator 22 for measurement and the quartz oscillator 23 for calibration enter the film formation range of the evaporation source, radiant heat the respective quartz oscillators receive from the evaporation source is substantially uniformized and the temperatures of the respective quartz oscillators may be caused to be substantially the same. By causing the sensor shutter 26 to be further in the open state for a predetermined length of time after the film formation source 21 returns from the film formation region to a film formation waiting region, a fixed amount of the film forming material is deposited on the quartz oscillator 23 for calibration. Therefore, the thickness of a thin film formed on the quartz oscillator 23 for calibration per unit time (film thickness value P₁) may be determined. At the same time, the thickness of the thin film formed on the quartz oscillator 22 for measurement per unit time (film thickness value M₁) may be determined. After a predetermined time period for determining the film thickness values P₁ and M₁ has passed, the sensor shutter 26 is closed. Here, the thickness of the thin film formed on the film formation object 30 (film thickness value) may be determined as βP₁ using the film thickness value P₁, and also may be determined as αM₁ using the film thickness value M₁.

By the way, the film forming material is deposited on the quartz oscillator 23 for calibration only in the calibration step, and thus, the amount of the deposited film of the film forming material is extremely small and the film thickness measurement error is small. On the other hand, a large amount of the film forming material is deposited on the quartz oscillator 22 for measurement, and thus the film thickness measurement error is large. Therefore, it does not necessarily follow that βP₁=αM₁. Therefore, a calibration coefficient (βP₁/αM₁) is calculated and the film thickness value determined using the quartz oscillator 22 for measurement after the calibration step is multiplied by the calibration coefficient. Then, the film thickness value determined using the quartz oscillator 22 for measurement is calibrated so as to be equal to a film thickness value (βP₁) determined using the quartz oscillator 23 for calibration which has a smaller error, and thus, in the film formation step after the calibration step, a film thickness value may be determined with only a small error. From the above, it can be said that the calibration step is a step for calculating the calibration coefficient (βP₁/αM₁).

Note that, as described above, in the film formation apparatus according to the present invention, the temperatures of the respective quartz oscillators (quartz oscillator 22 for measurement and quartz oscillator 23 for calibration) are substantially the same, and thus, in the calibration step, it is not necessary to correct the resonance frequencies of the quartz oscillators taking into consideration the temperature difference between the quartz oscillators due to radiant heat generated from the film formation source 21.

After the calibration step, a film thickness value M₁′ of the film forming material deposited on the quartz oscillator 22 for measurement is determined. Then, the temperature of the film formation source 21 is controlled by the thermoregulator (not shown) provided in the control system 40 so that a value αγ₁M₁′ obtained by multiplying M₁′ by a calibration coefficient γ₁(=(βP₁)/(αM₁)) and α is the desired film thickness value to be deposited on the film formation object 30.

The calibration step is appropriately performed as described above. In the film formation step which is performed after an n-th calibration step, the film forming material is deposited on the quartz oscillator 22 for measurement and a film thickness value Mₙ′ of the film forming material deposited per unit time is determined in the film thickness measurement device 41. Then, the temperature of the film formation source 21 is controlled by the thermoregulator (not shown) provided in the control system 40 so that a value α×(γ₁×γ₂× . . . ×γₙ)×Mₙ′ obtained by multiplying Mₙ′ by a calibration coefficient (γ₁×γ₂× . . . ×γₙ) and α is the desired film thickness value to be deposited on the film formation object 30.

The calibration step may be performed at an arbitrary timing based on the premise that the calibration step is performed in the middle of the film formation step, but may be performed every time a predetermined length of time passes, or may be performed every time the number of the film formation objects on which the film is formed reaches a predetermined number which is more than one. Further, the calibration step may be performed at the time when the amount of attenuation of the resonance frequency of the quartz oscillator 22 for measurement reaches a predetermined level, and may be performed at the time when the resonance frequency of the quartz oscillator 22 for measurement reaches a certain value.

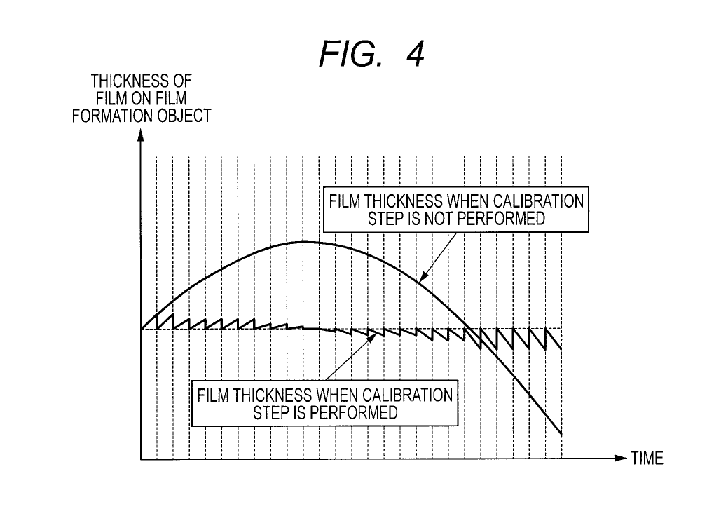

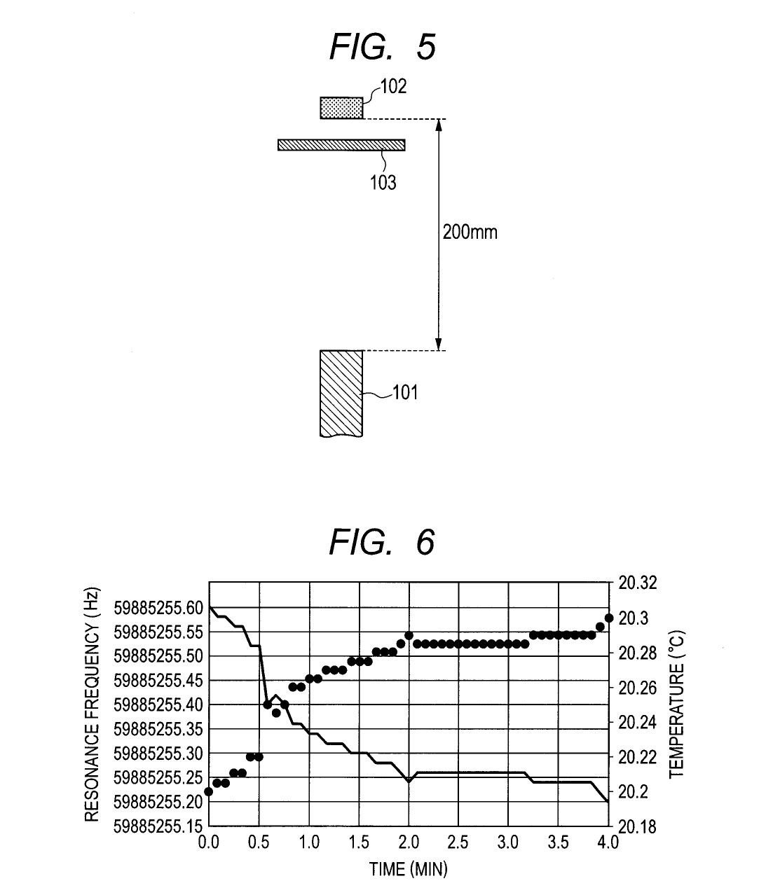

FIG. 4 is a graph which compares the thickness of the thin film formed on the film formation object 30 when the calibration step is performed to that when the calibration step is not performed. It is made clear that, as illustrated in FIG. 4, by appropriately carrying out the calibration step, the error in thickness of the film formed on the film formation object 30 may be reduced.

### EXAMPLE

### Example 1

The film formation apparatus illustrated in FIGS. 1A to 1D was used to form the film of the film forming material on the substrate.

In this example, the film was formed by reciprocating once the film formation source unit 20 with the transport distance being 1,000 mm and with the transport speed being 20 mm/s. The length in a longitudinal direction of the substrate (film formation object 30) was 500 mm.

Further, in this example, the heating temperature of the film formation source 21 was adjusted so that the thickness of the thin film of the film forming material formed on the substrate (film formation object 30) was 100 nm.

Further, in this example, as the quartz oscillator 22 for measurement and the quartz oscillator 23 for calibration, 6 MHz quartz oscillators having gold electrodes and manufactured by INFICON were used.

Meanwhile, in this example, the distance between the film formation source 21 and the substrate (film formation object 30) was 300 mm, and the distance between the film formation source 21 and the quartz oscillators (quartz oscillator 22 for measurement and quartz oscillator 23 for calibration) was 300 mm.

First, the preliminary step of the film formation was performed.

In this preliminary step, first, the substrate (film formation object 30) for measuring the film thickness was brought into the film formation chamber 10. After confirming that the amount of vapors of the film forming material released from the film formation source 21 had been stabilized at a desired value, movement of the film formation source unit 20 was started at a transport speed of 20 mm/s. Then, at the time when the film formation source unit 20 moved from the film formation waiting position to the film forming position, the sensor shutter was opened. Then, a thin film of the film forming material was deposited on each of the quartz oscillators (quartz oscillator 22 for measurement and quartz oscillator 23 for calibration) from the time when 30 seconds passed to the time when 90 seconds passed after the film formation source unit 20 completed the predetermined movement and was stopped at the film formation waiting position. Next, a thickness M (nm) of the thin film of the film forming material deposited on the quartz oscillator 22 for measurement and a thickness P (nm) of the thin film of the film forming material deposited on the quartz oscillator 23 for calibration were determined. Then, at the time when 91 seconds passed after the film formation source unit 20 was stopped at the film formation waiting position, the sensor shutter 26 was closed.

Then, the substrate (film formation object 30) for measuring the film thickness was taken out of the film formation chamber 10 using the transport mechanism (not shown), and then, the film thickness was measured using an optical film thickness measurement device or a contact film thickness measurement device. This determined the thickness of the thin film formed on the substrate for measuring the film thickness (film thickness value: t (nm)). Then, the ratio α of the thickness value of the film deposited on the substrate during 1 minute to the thickness value of the film deposited on the quartz oscillator 22 for measurement during 1 minute was expressed as α=t/M, while the ratio β of the thickness value of the film deposited on the substrate during 1 minute to the thickness value of the film deposited on the quartz oscillator 23 for calibration during 1 minute was expressed as β=t/p. Therefore, in the preliminary step, the film thickness value t (nm) of the substrate satisfied a relational expression of t=αM=βP.

Then, the step proceeded to the film formation step. In the film formation step, first, the substrate which was the film formation object 30 was brought into the film formation chamber 10 and was placed at a predetermined position. After the substrate was placed, movement of the film formation source unit 20 was started. After the movement of the film formation source unit 20 was completed, the substrate was taken out of the film formation chamber 10 and the film formation step was completed.

As the film formation step was performed multiple times, films were deposited on the quartz oscillator 22 for measurement, and thus, the film thickness measurement error of the quartz oscillator 22 for measurement gradually became larger. Therefore, the calibration step described below was performed.

A first calibration step was performed in the middle of a twentieth film formation step. More specifically, at the time when 50 seconds passed after the movement of the film formation source unit 20 was started from the film formation waiting position, the sensor shutter 26 was opened. Then, a thickness of the film of the film forming material deposited on the quartz oscillator 22 for measurement (film thickness value: M₁ (nm)) and a thickness of the film of the film forming material deposited on the quartz oscillator 23 for calibration (film thickness value: P₁ (nm)) from the time when 30 seconds passed to the time when 90 seconds passed after the film formation source unit 20 completed the movement and was stopped at the film formation waiting position were determined. Here, from M₁ and P₁, the film thickness of the film forming material formed on the substrate (film thickness value) was determined to be αM₁ (nm) or βP₁ (nm). However, the film thickness value αM₁ (nm) had a large error while the film thickness value βP₁ (nm) had a small error. Therefore, it does not necessarily follow that αM₁=βP₁. Therefore, the calibration coefficient γ₁=(βP₁)/(αM₁) was determined. In the film formation step after the calibration coefficient γ₁ was determined, the heating temperature of the film formation source 21 was adjusted so that the film thickness value M₁′ of the film deposited on the quartz oscillator 22 for measurement during 1 minute multiplied by the calibration coefficient γ₁ and the film thickness ratio α (α×γ₁×M₁′) was the desired film thickness of 100 nm to be deposited on the substrate.

However, if the heating temperature of the film formation source 21 is changed in the middle of the movement of the film formation source unit 20, the amount of the film forming material jetted from the film formation source 21 may hunt, or, the amount of the jetted film forming material may suddenly change to cause the film formed on the substrate to be nonuniform. Therefore, the heating temperature of the film formation source 21 was changed after the movement of the film formation source unit 20 was completed. In this way, hunting of the film forming material jetted from the film formation source 21 ended after the substrate was taken out and before the next substrate was brought in, and thus, the step was able to proceed to the next film formation smoothly.

As described above, the film formation step and the calibration step were performed. In the n-th calibration step which was performed in the middle of the 20n-th film formation step, the thicknesses of the thin films formed on the respective quartz oscillators were determined. More specifically, a thickness of the film of the film forming material formed on the quartz oscillator 23 for calibration during 1 minute (film thickness value: Pₙ (nm)) and a thickness of the film of the film forming material formed on the quartz oscillator 22 for measurement during 1 minute (film thickness value: Mₙ (nm)) were determined. Then, the calibration coefficient γₙ was determined as γₙ=(βPₙ)/(αMₙ). In the film formation step after the calibration coefficient γₙ was determined, the heating temperature of the film formation source 21 was adjusted so that the film thickness of the film of the film forming material formed on the quartz oscillator 22 for measurement during 1 minute (film thickness value Mₙ′) multiplied by the calibration coefficients determined in the first to the n-th calibration steps and the film thickness ratio α, that is, α×(γ₁×γ₂× . . . ×γₙ)×Mₙ′ was 100 (nm). Note that, as described above, the heating temperature of the film formation source 21 was changed after the movement of the film formation source unit 20 was completed.

As a result of such film formation, it was made clear that film formation was able to be performed without lowering the productivity with lowered film purity, which was caused by a holdup of the substrate (film formation object 30) in the film formation chamber 10, being prevented and with the film thickness being accurate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-247819, filed Nov. 4, 2010, and No. 2011-211811, filed Sep. 28, 2011, which are hereby incorporated by reference herein in their entirety.

What is claimed is:

1. A film formation apparatus, comprising:
an evaporation source for heating a film forming material and for releasing vapors of the film forming material;
a moving part for moving the evaporation source between a predetermined film formation waiting position and a predetermined film forming position with respect to a film formation object;
a quartz oscillator for measurement for measuring an amount of the film forming material formed on the film formation object; and
a quartz oscillator for calibration for calibrating the amount of the film forming material measured by the quartz oscillator for measurement,
wherein the quartz oscillator for measurement and the quartz oscillator for calibration are fixed above the predetermined film formation waiting position of the evaporation source.

2. The film formation apparatus according to claim 1, wherein the quartz oscillator for measurement and the quartz oscillator for calibration are fixed at positions at which distances from a center of the evaporation source to the quartz oscillator for measurement and the quartz oscillator for calibration are equal to each other and at which angles formed by the quartz oscillator for measurement and the quartz oscillator for calibration, and the center of the evaporation source are equal to each other.

3. The film formation apparatus according to claim 1, further comprising a temperature control part for controlling a temperature of the quartz oscillator for measurement and a temperature of the quartz oscillator for calibration to be substantially the same.

4. The film formation apparatus according to claim 1, further comprising a shutter in proximity to the quartz oscillator for calibration.

5. A film formation method of forming a film including a film forming material on an film formation object using the film formation apparatus according to claim 1, comprising:
a step of depositing a film including a film forming material on a film formation object at the film forming position;
a step of depositing a film including the film forming material on the quartz oscillator for measurement and the quartz oscillator for calibration at the film formation waiting position for a predetermined period of time;
a step of measuring a film thickness value of the film including the film forming material deposited on each of the quartz oscillator for calibration and the quartz oscillator for measurement in the predetermined period of time; and
a step of determining a calibration coefficient for calibrating the film thickness of the quartz oscillator for measurement based on a ratio of the film thickness values respectively measured from the quartz oscillator for calibration and the quartz oscillator for measurement.

6. A film formation method of forming a film including a film forming material on an film formation object using the film formation apparatus according to claim 4, comprising:
a step of depositing a film including a film forming material on a film formation object at the film forming position;
a step of bringing the shutter into an open state at a predetermined timing during the movement of the evaporation source at the film forming position;
a step of depositing a film including the film forming material on the quartz oscillator for measurement and the quartz oscillator for calibration at the film formation waiting position for a predetermined period of time;
a step of measuring a film thickness value of the film including the film forming material deposited on each of the quartz oscillator for calibration and the quartz oscillator for measurement in the predetermined period of time; and
a step of determining a calibration coefficient for calibrating the film thickness of the quartz oscillator for measurement based on a ratio of the film thickness values respectively measured from the quartz oscillator for calibration and the quartz oscillator for measurement.
